(19) United States
(12) Patent Application Publication
(10) Pub. No.: US 2013/0092549 A1
(43) Pub. Date: Apr. 18, 2013

(54) PROTON EXCHANGE MEMBRANE ELECTROLYSIS USING WATER VAPOR AS A FEEDSTOCK

(71) Applicants: Joshua M. Spurgeon, Pasadena, CA (US); Nathan S. Lewis, La Canada, CA (US); Philip Stephen Marcus, Alameda, CA (US)

(72) Inventors: Joshua M. Spurgeon, Pasadena, CA (US); Nathan S. Lewis, La Canada, CA (US); Philip Stephen Marcus, Alameda, CA (US)

(73) Assignee: CALIFORNIA INSTITUTE OF TECHNOLOGY, Pasadena, CA (US)

(21) Appl. No.: 13/437,812

(22) Filed: Apr. 2, 2012

Related U.S. Application Data
(60) Provisional application No. 61/470,860, filed on Apr. 1, 2011.

(51) Int. Cl. H01L 31/058; C25B 1/00; C25B 3/04; C25B 13/00

(52) U.S. Cl. CPC H01L 31/0586; C25B 13/00; C25B 1/003; C25B 3/04
USPC 205/340; 204/252; 204/265; 204/263

(57) ABSTRACT

A light-driven electrolytic cell that uses water vapor as the feedstock and that has no wires or connections whatsoever to an external electrical power source of any kind. In one embodiment, the electrolytic cell uses a proton exchange membrane (PEM) with an IrRuOₓ water oxidation catalyst and a Pt black water reduction catalyst to consume water vapor and generate molecular oxygen and a chemical fuel, molecular hydrogen. The operation of the electrolytic cell using water vapor supplied by a humidified carrier gas has been demonstrated under varying conditions of the gas flow rate, the relative humidity, and the presence or absence of oxygen. The performance of the system with water vapor was also compared to the performance when the device was immersed in liquid water.

### CROSS-REFERENCE TO RELATED APPLICATIONS

This application claims priority to and the benefit of co-pending U.S. provisional patent application Ser. No. 61/470,860 filed Apr. 1, 2011, which application is incorporated herein by reference in its entirety.

### STATEMENT REGARDING FEDERALLY FUNDED RESEARCH OR DEVELOPMENT

This invention was made with government support under DE-SC0004993/T-105066 awarded by the Department of Energy. The government has certain rights in the invention.

### THE NAMES OF THE PARTIES TO A JOINT RESEARCH AGREEMENT

This invention resulted from work under a joint research agreement between the California Institute of Technology and Lawrence Berkeley National Laboratory/Regents of the University of California.

### FIELD OF THE INVENTION

The invention relates to electrolytic cells in general and particularly to electrolytic cells that electrolyze water.

### BACKGROUND OF THE INVENTION

In the issue of Chemical Reviews published on Nov. 10, 2010, Arthur J. Nozik and John Miller wrote in an editorial that “[t]he direct conversion of solar photons to fuels produces high-energy chemical products that are labeled as solar fuels; these can be produced through nonbiological approaches, generally called artificial photosynthesis. The feedstocks for artificial photosynthesis are H₂O and CO₂, either reacting as coupled oxidation-reduction reactions, as in biological photosynthesis, or by first splitting H₂O into H₂ and O₂ and then reacting the solar H₂ with CO₂ (or CO produced from CO₂) in a second step to produce fuels through various well-known chemical routes involving syngas, water gas shift, and alcohol synthesis; in some applications, the generated solar H₂ itself can be used as an excellent gaseous fuel, for example, in fuel cells. But at the present time, there is no solar fuels industry. Much research and development are required to create a solar fuels industry, . . . As mentioned above, better and cheaper catalysts for H₂O oxidation and CO₂ reduction are critical to make advances in producing cost-effective solar fuels. . . . There has been a long and still ongoing search for the ideal semiconductors and architectures that can split water efficiently, without any external voltage applied, and are photostable.”

One approach that has been used to electrolyze water to hydrogen and oxygen is the photoelectrochemical approach. As described in M. G. Walter, E. L. Warren, J. R. McKone, S. W. Boettcher, Q. X. Mi, E. A. Santori and N. S. Lewis, Chem. Rev., 2010, 110, 6446-6473, “[t]he “Holy Grail” of solar energy conversion and storage is the photoelectrolysis of water using semiconductors as both the light absorber and energy converter, to store solar energy in the simplest chemical bond, H₂. . . . To accomplish this new photosynthesis, an economically viable water splitting cell, composed of stable semiconductors designed to split water directly at the semiconductor surface, needs to be developed. Photoelectrolysis can also be accomplished using photovoltaic (PV) modules connected directly to electrolyzers and/or catalytic electrodes.” The paper further states that “In the nearly 40 years since Honda and Fujishima's electrochemical photolysis report using TiO₂, the approach to solving the water splitting problem has been focused on evaluating new materials for both anodic/cathodic processes and integrating configurations that utilize photovoltaic cell junctions, to increase the obtainable voltage for a single or dual band gap device. The ultimate goal of these efforts is an efficient photoelectrolysis cell design that can simultaneously drive, in an unassisted fashion, both the hydrogen evolution and water oxidation reactions.” One of the problems with photoelectrolysis of water involves overvoltages that must be realized to drive the half cell reactions that produce hydrogen and oxygen, and the associated energetic losses that are incurred.

Additional descriptions of photoelectrolysis of water are presented in R. J. Davenport et al., J. Power Sources, 1991, 36, 235-250; S. A. Grigoriev et al., Int. J. Hydrogen Energy, 2006, 31, 171-175; S. P. S. Badwal et al., Ionics, 2006, 12, 7-14; L. L. Swette et al., J. Power Sources, 1994, 47, 343-351; F. Barbir, Sol. Energy, 2005, 78, 661-669; P. H. Choi et al., Solid State Ionics, 2004, 175, 535-539; J. H. Nie et al., J. Heat Transf.-Trans. ASME, 2008, 130; Y. J. Zhang et al., Int. J. Hydrogen Energy, 2007, 32, 400-404; E. Slavcheva et al., Electrochim. Acta, 2007, 52, 3889-3894; A. Di Blasi et al., J. Appl. Electrochem., 2009, 39, 191-196; O. Khaselev and J. A. Turner, Science, 1998, 280, 425-427; and S. Licht et al., J. Phys. Chem. B, 2000, 104, 8920-8924.

There is a need for improved systems and methods for electrolyzing water to generate molecular oxygen and a chemical fuel without resorting to electrical energy sources external to the electrolysis cell.

### SUMMARY OF THE INVENTION

According to one aspect, the invention features an illumination-driven apparatus. The illumination-driven apparatus comprises a separator having a first side and a second side opposite the first side, the separator configured to be permeable to an ionic reaction moiety and configured to be substantially impermeable to molecular moieties so as to separate a first molecular moiety present on the first side from a second molecular moiety present on the second side; an oxidation catalyst present on the first side of the separator, the oxidation catalyst configured to oxidize H₂O to produce molecular oxygen; a reduction catalyst present on the second side of the separator, the reduction catalyst configured to reduce a substance to produce a chemical fuel; a source of water vapor, the water vapor permitted to contact the first side of the separator and the oxidation catalyst; and a light absorber configured to absorb illumination, configured to provide electrons at a voltage sufficient to drive a desired chemical half-reaction at the reduction catalyst, and configured to accept electrons so as to drive another desired chemical half-reaction at the oxidation catalyst, the light absorber and the separator in mechanical contact so as to form a monolithic structure.

In one embodiment, the illumination-driven apparatus further comprises a first inlet port configured to permit the introduction of water vapor into the apparatus and a first outlet port configured to allow molecular oxygen to exit the apparatus.

In one embodiment, the chemical fuel is H₂.

In another embodiment, the chemical fuel is a carbonaceous fuel.

In one more embodiment, the carbonaceous fuel is a compound having a formula C_{M}H_{2N}O_{(2M+N-2P)}, in which M is an integer giving the number of moles of CO₂ consumed, N is an integer giving the number of moles of H₂O consumed, and P is an integer giving the number of moles of O₂ produced in a chemical reaction that produces one or more moles of C_{M}H_{2N}O_{(2M+N-2P)}.

In yet another embodiment, the ionic reaction moiety is H⁺.

In still another embodiment, the illumination-driven apparatus further comprises a chamber configured to contain a reagent, the chamber configured to permit the reagent to contact the second side of the separator and the reduction catalyst.

In a further embodiment, the illumination-driven apparatus further comprises a second inlet port configured to permit the introduction of the reagent into the chamber and a second outlet port configured to permit the removal of the chemical fuel from the chamber.

In yet a further embodiment, the light absorber configured to absorb illumination is configured to absorb illumination having an intensity of approximately 1 kilowatt per square meter or less.

In an additional embodiment, the illumination having an intensity of approximately 1 kilowatt per square meter or less is terrestrial solar illumination.

In still a further embodiment, the ionic reaction moiety is OH⁻.

According to another aspect, the invention relates to a method of generating a chemical fuel and molecular oxygen from a reaction medium containing water vapor. The method comprises the steps of providing an illumination-driven apparatus as described later in this paragraph; providing water vapor that contacts the first side of the separator and the oxidation catalyst; illuminating the light absorber; oxidizing H₂O to molecular oxygen at the oxidation catalyst; permitting H⁺ ions to permeate the separator; and performing a reduction at the reduction catalyst to produce a chemical fuel comprising hydrogen. The illumination-driven apparatus comprises a separator having a first side and a second side opposite the first side, the separator configured to be permeable to an ionic reaction moiety and configured to be substantially impermeable to molecular moieties so as to separate a first molecular moiety present on the first side from a second molecular moiety present on the second side; an oxidation catalyst present on the first side of the separator, the oxidation catalyst configured to oxidize H₂O to produce molecular oxygen; a reduction catalyst present on the second side of the separator, the reduction catalyst configured to reduce a substance to produce a chemical fuel; a source of water vapor, the water vapor permitted to contact the first side of the separator and the oxidation catalyst; and a light absorber configured to absorb illumination, configured to provide electrons at a voltage sufficient to drive a desired chemical half-reaction at the reduction catalyst, and configured to accept electrons so as to drive another desired chemical half-reaction at the oxidation catalyst, the light absorber and the separator in mechanical contact so as to form a monolithic structure.

In one embodiment, the illumination-driven apparatus further comprises a first inlet port configured to permit the introduction of water vapor into the apparatus and a first outlet port configured to allow molecular oxygen to exit the apparatus.

In another embodiment, the method is operated in a continuous process.

In one more embodiment, the reduction catalyst is a catalyst that reduces CO₂ to produce a carbonaceous fuel.

In one embodiment, the illumination-driven apparatus further comprises a chamber configured to contain a reagent, the chamber configured to permit the reagent to contact the second side of the separator and the reduction catalyst; and the method further comprises the steps of: providing a reagent containing CO₂ within the chamber; and performing the reduction step on a mixture of the reagent and the H+ ions to produce a chemical fuel comprising hydrogen and carbon.

In still another embodiment, the method is operated in a batch process.

In another embodiment, the illumination-driven apparatus further comprises a second inlet port configured to permit the introduction of the reagent into the chamber and a second outlet port configured to permit the removal of the chemical fuel from the chamber, the illumination-driven apparatus thereby enabled to support continuous operation of the step of oxidizing H₂O to molecular oxygen at the oxidation catalyst and continuous operation of the step of performing a reduction at the reduction catalyst to produce a chemical fuel comprising hydrogen.

In a further embodiment, the method is operated in a continuous process.

In yet a further embodiment, the illuminating step uses illumination having an intensity of approximately 1 kilowatt per square meter or less.

In an additional embodiment, the illuminating step uses terrestrial solar illumination.

The foregoing and other objects, aspects, features, and advantages of the invention will become more apparent from the following description and from the claims.

### BRIEF DESCRIPTION OF THE DRAWINGS

The objects and features of the invention can be better understood with reference to the drawings described below, and the claims. The drawings are not necessarily to scale, emphasis instead generally being placed upon illustrating the principles of the invention. In the drawings, like numerals are used to indicate like parts throughout the various views.

FIG. 1A is a schematic diagram of a cross section of the electrolyzer under operation with water vapor in UHP Ar(g) carrier gas as the feedstock.

FIG. 1B is a schematic diagram of a cross section of the electrolyzer under operation with liquid water as the feedstock.

FIG. 2 is a graph of the current density, J, vs. applied voltage, V, when varying the carrier gas flow rate.

FIG. 3 is a graph of the current density, J, vs. applied voltage, V, when varying the RH.

FIG. 4 is a graph of the current density, J, vs. applied voltage, V, when varying the RH in the cathode gas stream

FIG. 5 is a graph of the current density, J, vs. applied voltage, V, when varying the RH in the anode gas stream

FIG. 6 is a graph of the current density, J, vs. applied voltage, V, when using either air or inert carrier gas.

FIG. 7 is a schematic diagram that illustrates a first embodiment of the invention.

FIG. 8 is a schematic diagram that illustrates a second embodiment of the invention.

FIG. 9 is a schematic diagram that illustrates a third embodiment of the invention.

FIG. 10 is a schematic diagram that illustrates a fourth embodiment of the invention.

### DETAILED DESCRIPTION

We have constructed and operated a light-driven proton exchange membrane (PEM) electrolytic cell that uses water vapor as the feedstock and that has no wires or connections whatsoever to an electrical power source of any kind. In one embodiment, a proton exchange membrane electrolyzer was constructed using an IrRuOₓ water oxidation catalyst, a Nafion® membrane, and a Pt black water reduction catalyst. The current-voltage characteristics of the proton exchange membrane electrolyzer under operation with water vapor from a humidified carrier gas, have been examined as a function of the gas flow rate, the relative humidity, and the presence of oxygen. The performance of the system with water vapor was also compared to the performance when the device was immersed in liquid water. With a humidified Ar(g) input stream at 20° C., an electrolysis current density of 10 mA cm⁻² was sustained at an applied voltage of ˜1.6 V, with a current density of 20 mA cm⁻² observed at ˜1.7 V. In the system evaluated, at current densities>40 mA cm⁻² the electrolysis of water vapor was limited by the mass flux of water to the PEM. At <40 mA cm⁻², the electrolysis of water vapor supported a given current density at a lower applied bias than did the electrolysis of liquid water. The relative humidity of the input carrier gas strongly affected the current-voltage behavior, with lower electrolysis current density attributed to dehydration of the PEM at reduced humidity values. The results demonstrate that, with sufficiently active catalysts, an efficient solar photoelectrolyzer can be operated only with water vapor as the feedstock, even at the low operating temperatures that may be required without active heating. These systems and methods offer a route to avoid the light attenuation and mass transport limitations that are associated with bubble formation in these systems.

The membrane-based electrolysis of water is similar in concept, but differs significantly in operational detail, from the sunlight-driven membrane-based photoelectrolysis of water. Specifically, to minimize capital expenditures, water electrolyzers are typically operated at high (>1 A cm⁻² at 80-90° C.) current densities. In contrast, the unconcentrated solar photon flux would limit, under optimal operating conditions, the current density of an integrated membrane-based water photoelectrolysis device, in which electrocatalysts embedded in a membrane are deposited onto the surface of light-absorbing semiconductor structures, to <20 mA cm⁻². A second practical difference involves the impact of gas bubbles on the operation of the device. The flow of gas bubbles can provide active transport of liquid water to the surface of the electrodes, but bubble production can also deleteriously affect the steady-state current density at a given potential by reducing the contact area between the water and the electrocatalyst at either the anode or the cathode of an electrolysis unit. The production of bubbles is potentially of additional significance in a membrane-based photoelectrolysis system because the bubbles can refract and/or scatter the incoming incident illumination away from the photoactive electrode, thereby deleteriously affecting the overall performance of the solar-driven water electrolysis system. Hence, strategies to minimize the effects of, or avoid completely, the formation of H₂ and O₂ bubbles during the electrolysis of water are highly desirable.

The use of water vapor as the system input feedstock, as opposed to liquid water, eliminates any deleterious effects associated with the formation of H₂ or O₂ bubbles during water electrolysis. A water vapor feedstock is problematic for conventional electrolyzers due to the resultant mass transport limitations of reactant at the current densities at which electrolysis systems are typically operated. Such a constraint is, however, greatly relaxed at the hundred-fold lower current densities that will be produced by membrane-based sunlight-driven photoelectrolysis systems operated under unconcentrated sunlight. We have examined the performance limitations that accompany the use of water vapor, instead of liquid water, as a feedstock in a solar-driven membrane-bound electrolysis system driven by unconcentrated sunlight.

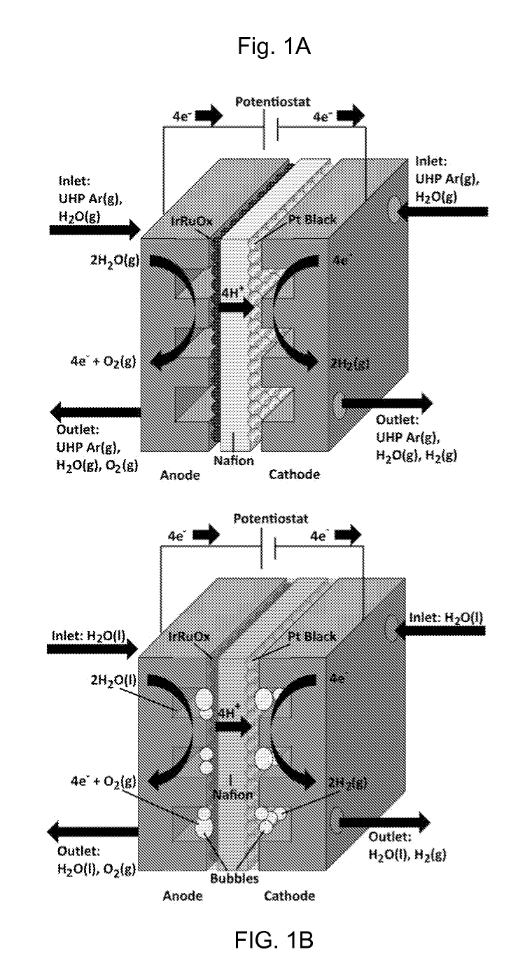

We have used a commercially available, membrane-based water electrolysis unit as a demonstration system to evaluate the mass-transport limitations that are associated with the use of water vapor instead of liquid water as the feedstock. FIG. 1A is a schematic diagram of a cross section of the electrolyzer under operation with water vapor in UHP Ar(g) carrier gas as the feedstock. FIG. 1B is a schematic diagram of a cross section of the electrolyzer under operation with liquid water as the feedstock. The product gases will form bubbles in liquid water, but bubble formation will be absent when water vapor is used as the electrolysis feedstock.

Water electrolysis based on catalyst-coated Nafion®-type sulfonated tetrafluoroethylene based fluoropolymer-copolymer proton exchange membranes is well-characterized both experimentally and operationally, being in essence the operation of a PEM-based H₂/O₂ fuel cell in reverse (that is, generating H₂ and O₂ from H₂O, rather than producing H₂O from H₂ and O₂). However, little work has been reported to date on the use of gaseous water vapor as the feedstock to such electrolyzers. See S. D. Greenway, E. B. Fox and A. A. Ekechukwu, Int. J. Hydrogen Energy, 2009, 34, 6603-6608; S. Sawada, T. Yamaki, T. Maeno, M. Asano, A. Suzuki, T. Terai and Y. Maekawa, Prog. Nucl. Energy, 2008, 50, 443-448. Sawada et al. have demonstrated the feasibility of the concept, but have not elucidated the effects of relative humidity (RH) or ambient temperature conditions on the performance of the electrolyzer. The system studied also did not use the best available catalysts and therefore could not definitively allow evaluation of any change in overpotentials that might occur when water vapor was used instead of liquid water.

We have used a PEM electrolyzer that contained a Nafion® membrane and highly active water oxidation and water reduction catalysts to investigate the changes in overpotential, as well as the mass transport limitations, that are associated with the substitution of water vapor for liquid water as the feedstock for such electrolyzer systems. We have demonstrated that, with active catalysts and with a well-hydrated membrane, an electrolysis current density of >20 mA cm⁻² can be sustained at room temperature (20° C.) by the use of water vapor as a feedstock. We also show that at moderate current densities, relatively little change in the performance of the electrolysis unit results when water-saturated inert gas is used instead of liquid water as the electrolyzer feedstock.

### PEM Electrolyzer System

A commercially available demonstration fuel cell apparatus (available from Clean Fuel Cell Energy, LLC, 3350 Ulmerton Road, Suite 23, Clearwater, Fla. 33762) was used to construct the electrolyzer apparatus. In order to perform the experiments that are described hereinbelow, the fuel cell apparatus was operated in reverse, as an electrolyzer. The electrolyzer included two graphite end plates (one for the anode and one for the cathode) that had serpentine gas flow channels (1.8 mm wide, 2.0 mm deep, spaced 1.0 mm apart) grooved into the side of the plate that faced the membrane. The channels represented ˜80% of the active area of the membrane that was directly exposed to the input gas flow. In other embodiments, a serpentine pattern having narrower channels and closer spacing may be advantageous to better match the electrical characteristics of the catalysts (such as charge carrier diffusion lengths) and the mechanical spacing of the graphite contacts to the catalysts. The membrane was Nafion® (available from Lynntech Inc., 2501 Earl Rudder Freeway South, Suite 100, College Station, Tex. 77845, Nafion 115, 127 μm thick) that had an anode catalyst loading of 3.0 mg cm⁻² of IrRuOₓ (1:1 IrO₂:RuO₂) and a cathode catalyst loading of 3.0 mg cm⁻² of Pt black. The projected active area of the membrane was 5 cm². Gas diffusion layers were not used, due to the instability under electrolysis conditions of the carbon-based material in a typical gas diffusion layer.

Ultra-high purity Argon gas (UHP Ar(g)) (>99.99%) was used as the carrier gas in all experiments, except for those specifically identified experiments in which the carrier gas was either N₂(g) (>99.99%) or house air (1.10±0.15 ppth of water vapor). The carrier gas was saturated with water vapor by passing the gas at a flow rate of 0.04-0.5 L min⁻¹ (controlled by flowmeters from Chemglass) through a bubbler that had been filled with 18 MΩ-cm resistivity deionized H₂O, obtained from a Barnstead Nanopure system. The humidified gas stream was mixed with a dry gas stream, both at controlled flow rates, to create a gas flow of the desired relative humidity (RH). The system produced precise (±2% RH) and reproducible humidity values in the gas flow stream, as monitored by a relative humidity probe (Omega, RH-USB sensor). A water-saturated carrier gas stream to which dry gas had not been added had a RH of ˜95%. To minimize the back diffusion of ambient oxygen into the electrolysis unit, the output stream from the electrolyzer was bubbled through an oil bath. For the electrolysis of liquid water, the electrolyzer cell was immersed in 18 MΩ-cm resistivity H₂O(l) that had been deoxygenated by bubbling with Ar(g) for >1 h. All experiments were conducted at an ambient temperature of 20° C.

### Data Collection Procedures

The electrolyzer was allowed to equilibrate at open circuit for more than 2 h before measurements of the current density-voltage (J-V) behavior under each set of experimental conditions (flow rate, RH, etc.) were performed. An SI model 1286 Schlumberger potentiostat was used to apply a DC bias to the electrolyzer cell, and to measure the current through the cell, through current collector pins in contact with each of the graphite end plates of the electrolysis unit. The current reached an approximate steady state value after more than 300 s at each applied bias. The J-V behavior was also measured by sweeping the voltage, at a scan rate of 1 mV s⁻¹, from open circuit to 2.6 V. The current values measured at a given potential in the scan were in close agreement with the current that was measured at that same potential after 300 s under potentiostatic conditions. The current density was determined using the projected area of the active part of the membrane electrode assembly without correcting for the estimated area in direct contact with the graphite end plates of the electrolyzer. In an electrolyzer for use in a system having no electrical connection to an external power source, a photoabsorber such as a photovoltaic cell or photovoltaic array can be used to provide the potential between the cathode and the anode, to provide the needed charge carriers, and to prevent the electrolyzer from operating as a fuel cell.

### Experimental Results

A. Gaseous vs. Liquid Water Feedstocks

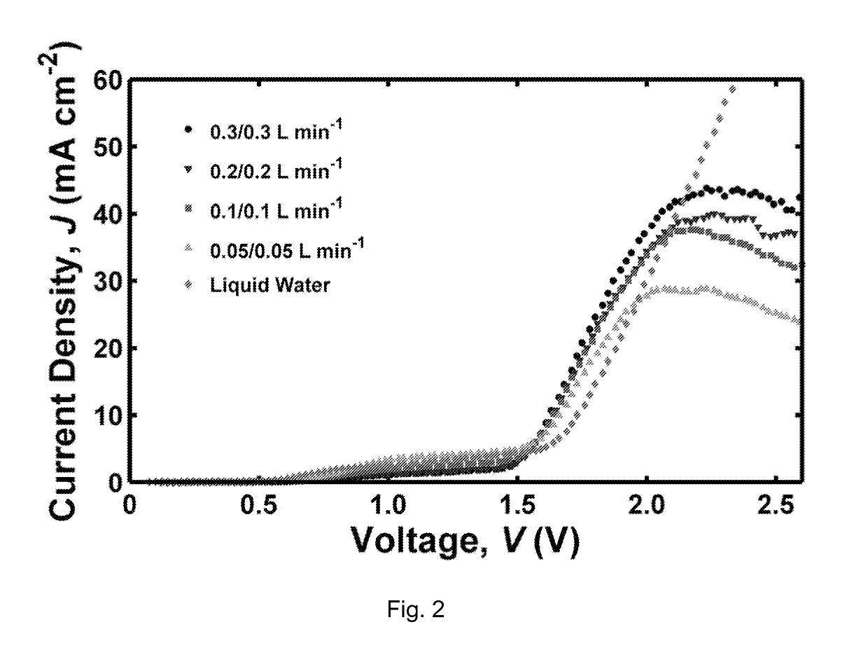

FIG. 2 depicts the J-V behavior of the electrolyzer with liquid water as a feedstock relative to the behavior observed with a flow of Ar(g) saturated with water vapor as the feedstock. The information provided in the legend is for the anode/cathode, specifying the gas flow rate to each electrode. The carrier gas was UHP Ar(g) with a RH of 95% in each case, and the operating temperature was 20° C. The data represented by diamonds is the J-V behavior of the electrolyzer immersed in liquid water at 20° C. For V<2 V (i.e., J<30 mA cm⁻²), the performance was very similar in both cases, and at a given voltage more current was observed with water vapor as the feedstock than with liquid water as the feedstock. The limiting electrolysis current density increased with increasing Ar(g)/H₂O(g) flow rate, from a value of ˜25 mA cm⁻² at 0.05 L min⁻¹ to ˜40 mA cm⁻² at a flow rate of 0.3 L min⁻¹ to each electrode. In contrast, when immersed in liquid water, the electrolyzer did not reach a limiting current density within the experimentally measured voltage range, with the current density exceeding 70 mA cm⁻² at V=2.5 V at 20° C.

### B. Relative Humidity

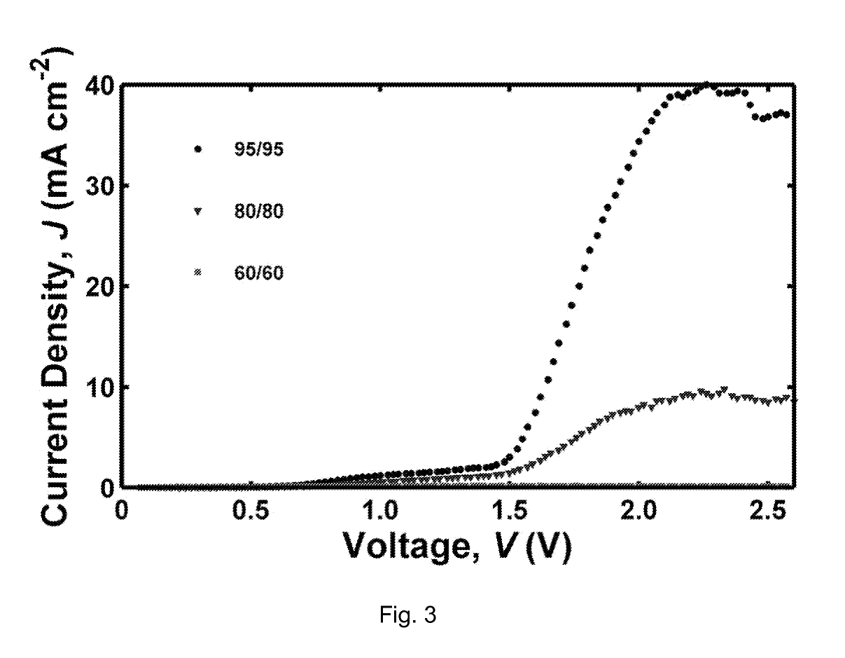

Variations in the RH of the input carrier gas stream significantly impacted the J-V behavior of the electrolyzer. FIG. 3 is a graph of the current density, J, vs. applied voltage, V, when varying the RH. The information provided in the legend is for the anode/cathode, specifying the RH of the gas stream to each electrode. The carrier gas was UHP Ar(g) at a flow rate of 0.2 L min⁻¹ in each case, and the operating temperature was 20° C.

When the RH was decreased equally to each electrode as illustrated in FIG. 3, the current density dropped precipitously, with negligible electrolysis current sustained at a RH of ≦60%. The decline in performance was less severe when the gas was fully humidified to one electrode in the system.

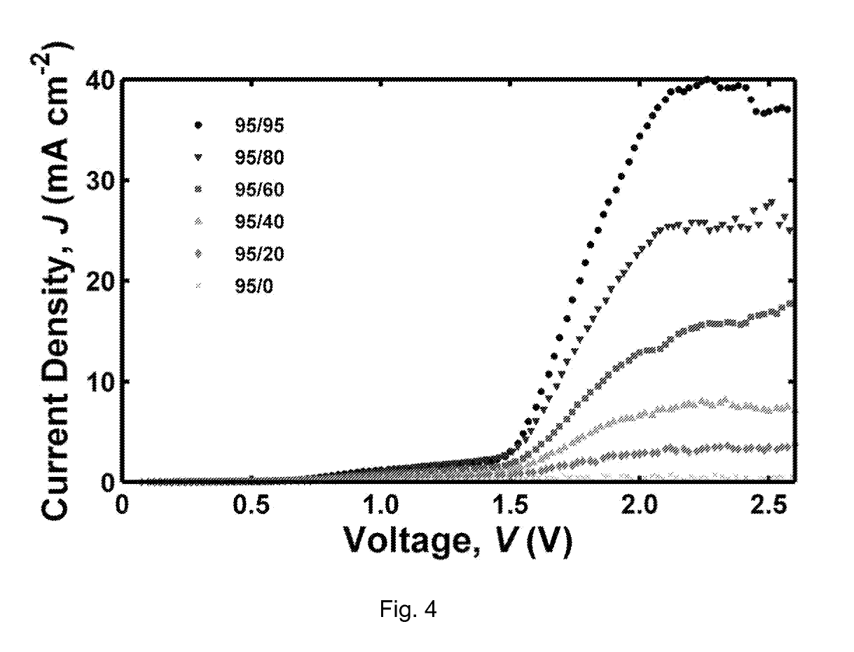

FIG. 4 is a graph of the current density, J, vs. applied voltage, V, when varying the RH in the cathode gas stream. The information provided in the legend is for the anode/cathode, specifying the RH of the gas stream to each electrode. The carrier gas was UHP Ar(g) at a flow rate of 0.2 L min⁻¹ in each case, and the operating temperature was 20° C. A reduction in the water content of the gas feed was somewhat more tolerable when only the RH to the cathode gas feed was varied, with a non-negligible electrolysis current requiring a RH of ≧20% as illustrated in FIG. 4.

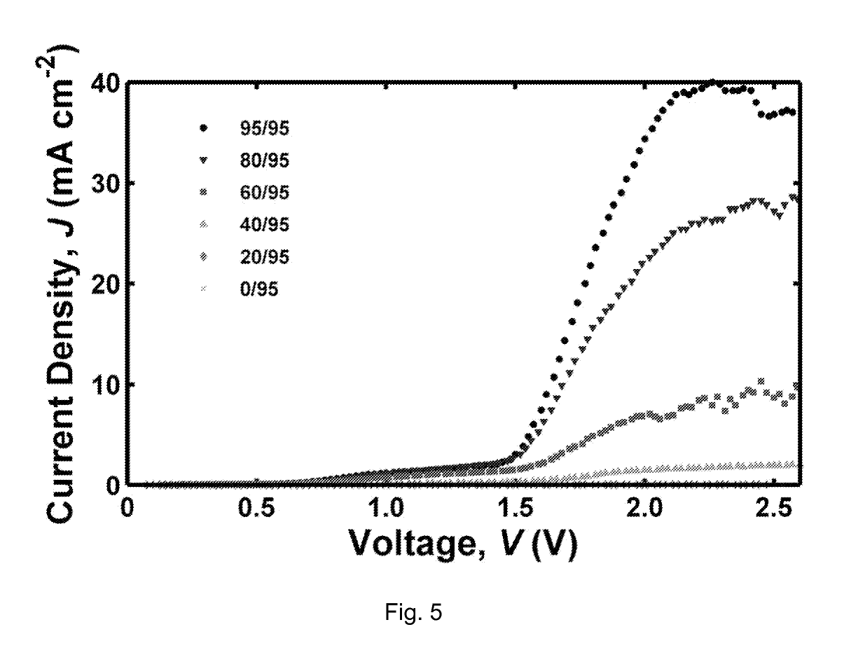

FIG. 5 is a graph of the current density, J, vs. applied voltage, V, when varying the RH in the anode gas stream. The information provided in the legend is for the anode/cathode, specifying the RH of the gas stream to each electrode. The carrier gas was UHP Ar(g) at a flow rate of 0.2 L min⁻¹ in each case, and the operating temperature was 20° C. When the RH in the gas feed to the anode was varied, a non-negligible electrolysis current required a RH of ≧40% as illustrated in FIG. 5 in the input feed at 20° C.

### C. Presence of O₂ in the Input Gas Stream

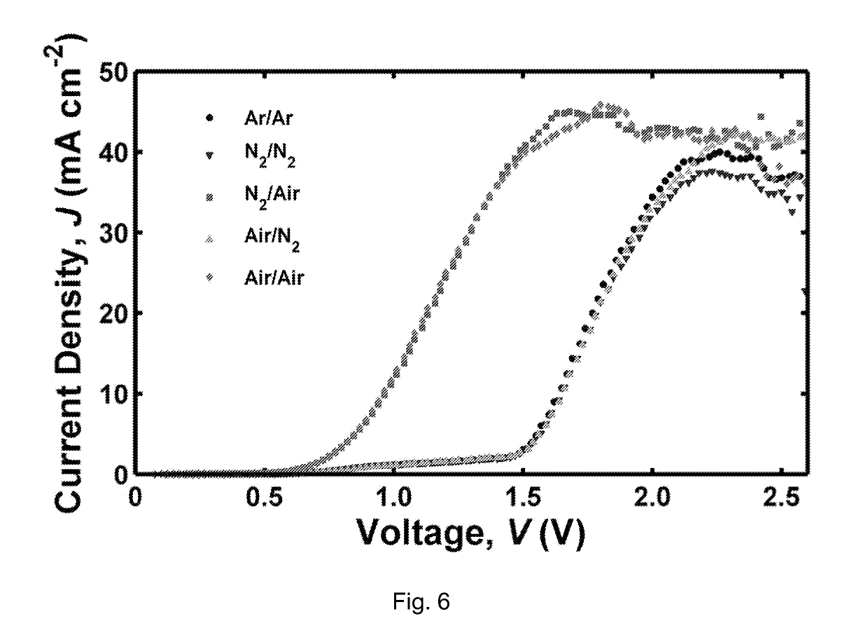

FIG. 6 is a graph of the current density, J, vs. applied voltage, V, when using either air or inert carrier gas. The information provided in the legend is for the anode/cathode, specifying which carrier gas was supplied to each electrode. The gas flow rate was 0.2 L min⁻¹ at a RH of 95% to each electrode, and the operating temperature was 20° C. FIG. 6 shows the effect on the J-V behavior of using humidified air, Ar(g), or N₂(g) as the carrier gas to the anode and/or cathode of the electrolyzer. No significant difference was observed in the J-V performance of the electrolyzer when the carrier gas introduced to both electrodes was changed from Ar(g) to N₂(g). In both cases, the current density remained low (J<2 mA cm⁻²) until V>1.5 V, at which point the current density increased rapidly, reaching values of 10 mA cm⁻² at ˜1.6 V and 20 mA cm⁻² at ˜1.7 V. For V greater than ˜2.1 V, the current density plateaued at about 35-40 mA cm⁻².

Nearly identical behavior was observed when air was supplied to the anode and an inert gas was supplied to the cathode. However, use of air as the carrier gas introduced to the cathode, with either an inert gas or air introduced to the anode, produced a significant increase in J for V<1.5 V. Specifically, with air flowing to the cathode, J=10 mA cm⁻² was observed at V˜1.0 V, and J=20 mA cm⁻² was observed at ˜1.2 V. For V greater than 1.5 V, the current density remained at about 40-45 mA cm⁻².

### Analysis

A. Gaseous vs. Liquid Water Inputs

The experiments demonstrate that electrolysis in a membrane-based system can clearly be sustained at J=10-20 mA cm⁻² with water vapor as the feedstock. The flux of water molecules to the membrane became a limiting factor at higher current densities. Higher flow rates of humidified gas to the electrolyzer resulted in an increased mass flux of water to the membrane surface, reducing the effect of mass transport limitations. Increasing the flow rate of humidified Ar(g) to each electrode, from 0.05 L min⁻¹ to 0.3 L min⁻¹, increased the limiting electrolysis current density by ˜60% (from 25 mA cm⁻² to 40 mA cm⁻²). For a given photoelectrolysis system with semiconductor light absorbers producing a set photovoltage and with an overpotential dependent upon the catalysts employed, the active flow of humidified gas to the electrodes could be optimized to reach the maximum attainable current density without an unnecessarily high flow rate. We also note that our observations are lower bounds on the attainable current density in such a system because no gas diffusion layer was used and the graphite end plates were directly attached to the catalyst layer, so only the portion (˜80%) of the catalyst that was directly exposed to the gases, and then only the fraction that was within useful electrical contact laterally to the electrodes, was electrochemically active as configured in this test system.

In the presence of highly active electrocatalysts, the onset of significant electrolysis current density occurred at a higher voltage for liquid, rather than gaseous, water as the feedstock (See FIG. 2). At 20 mA cm⁻², this difference resulted in a ˜140 mV discrepancy between the applied bias required under a flow rate of 0.2 L min⁻¹ of humidified Ar(g) relative to the applied bias required using liquid water. The reduced voltage required for electrolysis when using water vapor can be partially attributed to the difference in ΔG_{f}⁰ (standard Gibbs free energy of formation) between liquid water and gaseous water, with ΔG_{f}⁰ [H₂O(l)]=−237.18 kJ mol⁻¹, and ΔG_{f}⁰ [H₂O(g)]=−228.59 kJ mol⁻¹. The ΔG⁰ relates to the standard potential of the cell reaction, E⁰, by:

ΔG⁰=−nFE⁰ (Eqn. 1)

where n is the number of electrons passed per H₂O molecule reacted (n=2), and F is Faraday's constant (F=96,485 C). This equation results in thermodynamic water-splitting potentials of E⁰ [H₂O(l)]=1.229 V, and E⁰ [H₂O(g)]=1.185 V. Therefore, in the thermodynamic limit, the electrolysis of liquid water requires an extra 44 mV of bias as compared to the electrolysis of water vapor. This difference only partially accounts for the observed shift in the J-V behavior between electrolysis with H₂O(l) vs. H₂O(g) as the feedstock. The remaining voltage difference is attributed, at least in part, to a reduced contact area between liquid water and the catalyst due to bubble formation. Additionally, part of the voltage shift between gaseous vs. liquid water inputs may be due to a change in the catalytic overpotential, due to the different local environments at the membrane surface under these different conditions. This shift in the voltage for electrolysis indicates that when low current densities are required (≦20 mA cm⁻²), the use of water vapor appears to be preferable to liquid water as the feedstock. Notably, the fuel cell described herein was not an ideal electrolyzer, and the use of a more optimized device may yield further increases in performance for both liquid and gaseous water feedstocks.

### B. Relative Humidity

The effect of the RH of the gas stream on the J-V behavior is an important factor when assessing the tolerance of the electrolyzer to ambient conditions. FIG. 3 shows that even a minor decrease in RH at 20° C. produced a significant decrease in electrolyzer performance, with no observable current at a RH of ≦60%. The steep drop in the J-V behavior of the electrolyzer with RH is believed to be due to drying of the membrane. Nafion® must be kept well-hydrated to maintain its high ionic conductivity because water preferentially fills hydrophilic, negatively charged channels which then enable the selective transfer of protons across the membrane. Without sufficient water present, the channels constrict and the membrane conductivity is significantly reduced. The greater the reduction of the RH below 100%, the more moisture will evaporate from the membrane, decreasing the conductivity and impacting the steady state J-V behavior of the electrolyzer.

Although the difference between the J-V behavior with reduced humidity at the cathode (See FIG. 4) and the J-V behavior with reduced humidity at the anode (See FIG. 5) was fairly minor, the electrolyzer performed somewhat better when the low RH values (≦60%) were at the cathode. This is consistent with expectations because the decomposition of H₂O molecules occurs at the anode, hence low water content at the anode as compared to the cathode would thus be expected to have a more pronounced effect on the J-V behavior of the system. Clearly, providing a fully humidified feed to one electrode partially mitigated the membrane drying effect relative to the case of reduced humidity to both electrodes (See FIG. 3). If the membrane can be kept well-hydrated, it may be possible to sustain J-V behavior similar to that shown in FIG. 2 even with lower RH in the input gas streams. This hydration may be possible by periodically or continually sprinkling or misting the membrane with water. Alternatively, it is believed that a Nafion® membrane could be fabricated with a web of hydroponic polymer integrated into the membrane that would wick water from a reservoir at the side of the water-splitting device.

### C. Presence of O₂ in the Input Gas Stream

To produce the most economically viable solar chemical fuel generation device, photoelectrolysis should preferably operate with minimal active input to the system—i.e., passive heating only and little or no required pumping of reactants. Ideally, chemical fuel could be produced simply by photoelectrolyzing water vapor directly from the ambient atmosphere. As shown in FIG. 6, the introduction of air to the anode alone did not result in any noticeable change to the J-V behavior of the electrolyzer as compared to its performance under humidified inert gas. Because O₂(g) is produced at the anode during water-splitting, the addition of O₂(g) in air to the carrier gas feed appears to have no further effect on the behavior of the electrolyzer. However, the presence of O₂(g) in air at the cathode had a strong effect on the J-V behavior of the electrolyzer (See FIG. 6). Under these conditions, the cathode is essentially performing the opposite reaction to the anode, reducing O₂(g) back into water by combining O₂(g) with protons coming from the membrane. The onset of current occurred for V greater than 500 mV, rather than at 0 V, due to the catalytic overpotential. Thus, because the reduction of O₂(g) is thermodynamically favored relative to H₂(g) evolution, the steady-state flux of O₂(g) to the catalyst sites at the cathode should preferably be kept low to prevent O₂(g) reduction from significantly impairing the overall cell efficiency. Above 1.5 V, H₂(g) evolution will occur at the cathode as well, competing kinetically with O₂(g) reduction in consuming protons. If H₂(g) is produced rapidly enough relative to the input air flow rate, the H₂(g) could purge the O₂(g) from the catalyst surface, ensuring maximum H₂(g) production. Of course, the H₂(g) will need to be separated from any O₂(g) in the cathode effluent downstream before the gases recombine to form water. If no O₂(g) is input to the cathode, the cathode should self-purge and become depleted of O₂(g), except for the steady-state O₂(g) crossover from the anode. Therefore, while it is clearly possible to expose the anode of a water vapor photoelectrolysis system to the atmosphere during operation in the field, the introduction of air to the cathode is only feasible under conditions for which the reduction of O₂(g) is not replacing the evolution of H₂(g).

To ensure that the observed J-V behavior was due exclusively to splitting water, UHP Ar(g) was the sole carrier gas used in all other experiments reported herein. It was advantageous to bubble the output gas stream through an oil bath in order to prevent the diffusion of ambient oxygen into the cathode compartment. Any remaining nonzero current observed at voltages below 1.23 V can thus be attributed to ambient O₂(g) diffusing directly into the demonstration fuel cell which served as the electrolyzer.

### D. Temperature

The experiments reported herein were all conducted at a relatively low temperature (20° C.) for electrolysis in order to show what is expected to happen in photoelectrolysis device that does not include active heating, to provide an inexpensive device. In other embodiments, passive heating elements (i.e., a black body layer to produce heat by collecting light not absorbed by the semiconductor components) may enable operation at higher than ambient temperatures. Previous experimental results and electrolyzer models based on Butler-Volmer kinetics indicate that increased temperature is expected to enable higher current densities for a given applied bias. Additionally, fully humidified gas at higher temperature has a greater water content, which may raise the limiting current density of electrolysis sustained by water vapor. The current densities reported herein should therefore be considered to be the lower bounds attainable with active water oxidation and reduction catalysts in some embodiments. However, these values may be particularly relevant for evaluating the system operation with passive heating of the device in cooler climates. Initial experiments indicated that water management and hydration of the membrane became increasingly critical at higher operating temperatures, with a RH of <100% leading to membrane drying, and consequently to a strong decrease in the electrolysis current density. The operation of an electrolyzer with water vapor at higher temperatures may require a scheme to keep the Nafion® membrane hydrated. In other embodiments, the use of an alternative ionomer that is less sensitive to its water content may be advantageous.

### E. System Engineering Considerations

The ability to operate on a water vapor feedstock is believed to ease the system engineering constraints associated with a PEM-based photoelectrolyzer. In a complete, membrane-integrated device, however, light must be managed and optimally distributed between the semiconductor photoanode and photocathode without significant absorption losses to the catalysts or membrane, and all materials must be stable at the pH of the operating environment. The membrane should be able to incorporate and support the semiconductor components, electrically connect the photoanode to the photocathode, exchange ions to prevent the buildup of a pH gradient, separate the gaseous reaction products, and be transparent to the above-bandgap illumination. Additionally, in a liquid environment, the device advantageously should be engineered to minimize bubble trapping at the semiconductor/catalyst surface. Operation in a gaseous environment eliminates this issue; however, high surface area semiconductor electrodes advantageously should be covered with polymer electrolyte to maximize the three-phase contact area.

We have demonstrated PEM electrolysis using water vapor at current densities sufficient to support an efficient photoelectrolysis system operating under 1 Sun illumination. It is believed that it should therefore be possible to avoid the disadvantageous effects of bubble formation during operation of a solar chemical fuel generation device by utilizing gaseous, rather than liquid, water as the feedstock. At 20° C. with an IrRuOₓ water oxidation catalyst and a Pt black reduction catalyst, an applied bias of ˜1.7 V resulted in a current density of 20 mA cm⁻². Under these conditions, a water vapor feedstock supported electrolysis current densities of less than 30 mA cm⁻² at a lower applied bias than was required to attain the same current density in liquid water. Decreasing the RH in the input carrier gas stream strongly degraded the electrolyzer performance, which is believed to be due to drying of the Nafion® membrane. It is believed that if the membrane can be kept well-hydrated, it will be possible to sustain electrolysis by exposing the electrodes to ambient water vapor in air; however, the air flow rate to the cathode should preferably be carefully chosen to prevent O₂(g) reduction from decreasing the H₂(g) evolution rate.

### Light-Driven Membrane Apparatus

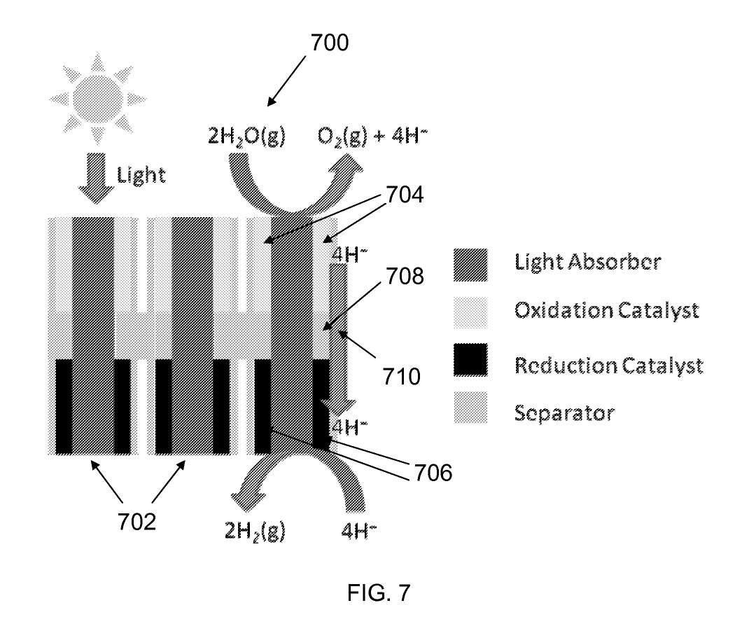

FIG. 7 is a schematic diagram of an embodiment 700 of the invention, shown performing as an example the generation of H₂ and O₂ from water. In FIG. 7, a light absorber 702, which in some embodiments comprises semiconductor components, absorbs incident light, for example AM1 solar radiation, or similar illumination having approximately 1 kilowatt per square meter of incident energy or less, and generates electrons and holes at a certain potential. The holes go to the anode 704 comprising an oxidation catalyst and oxidize H₂O provided by water vapor. Equivalently, one can state that the anode extracts electrons from H₂O, thereby oxidizing the H₂O⁻ to molecular oxygen, and the electrons flow into the light absorber 702. The electrons generated in the light absorber go to the cathode 706 comprising a reduction catalyst and reduce protons (H⁺) to make molecular hydrogen. A separator 708, which in some embodiments is an ion exchange membrane, separates the oxygen generation region from the hydrogen generation region, but permits a flux (represented by arrow 710) of excess protons (H⁺) to pass from the side of the separator in contact with the anode 704 to the side of the separator in contact with the cathode 706. The light absorber 702 and the separator 708 are mechanically in contact so as to form a monolithic structure. For the purposes of this disclosure, the term “monolithic structure” is defined to mean a structure in which the light absorber and the separator are physically connected and the light absorber is electrically connected to the catalysts present on the two opposed sides of the separator, rather than being separate units that are later electrically connected with wires.

In different embodiments, the arrangement of the light absorber and the separator can vary. In general, the light absorber and the separator can be distinct regions of a single structure, which in some embodiments can be constructed out of a plurality of repeating mechanical units that are monolithically interconnected, rather than being limited to one light absorber and one separator. For example, one can envision various two dimensional arrays of interconnected separator regions and light absorber regions that can cover an area so as to absorb significant amounts of incident illumination.

The electrochemistry that occurs in the example shown in FIG. 7 can be described by two half reactions:

2 H₂O(g)→O₂(g)+4 H⁺+4 e⁻ Anode reaction (Rxn. 1)

4 H⁺+4e⁻→2 H₂(g) Cathode reaction (Rxn. 2)

Summing the two half-reactions gives the overall reaction for splitting water to generate molecular oxygen and a chemical fuel, molecular hydrogen, on the two sides of the apparatus:

2 H₂O(g)→O₂(g)+2 H₂(g) Overall reaction (Rxn. 3)

The reaction that takes place on the cathode can be supported entirely by the flux of protons (H+) that flow across the separator, and no net provision of protons on the cathode side from another source is needed. While no source if hydrogen needs to be provided, it may be advantageous to have a source of water vapor on the hydrogen generation side of the apparatus, if only to maintain a level of hydration in the separator. In other embodiments, a carrier gas may be advantageously provided to carry away the hydrogen to a collection location, and to maintain a pressure in the approximate range of 1 atmosphere (e.g., ambient pressure.

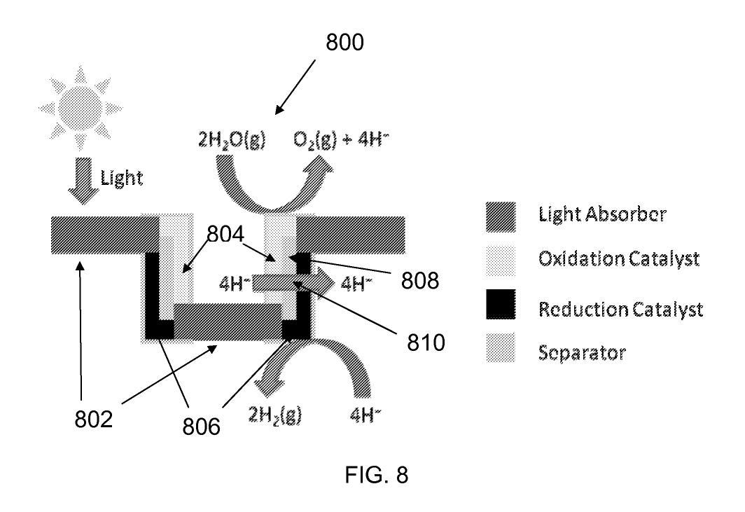

In a second embodiment 800 illustrated in FIG. 8, the separator, the catalysts and light absorber components could be arranged differently than in FIG. 7. In FIG. 8, semiconductor components 802 absorb incident light and generate electrons and holes at a certain potential. The holes go to the anode 804 comprising an oxidation catalyst and oxidize H₂O provided by water vapor. The electrons generated in the light absorber go to the cathode 806 comprising a reduction catalyst and reduce protons (H⁺) to make molecular hydrogen. A separator 808, which can be an ion exchange membrane, separates the oxygen generation region from the hydrogen generation region, but permits a flux (represented by arrow 810) of excess protons (H⁺) to pass from the oxygen generation region to the hydrogen generation region.

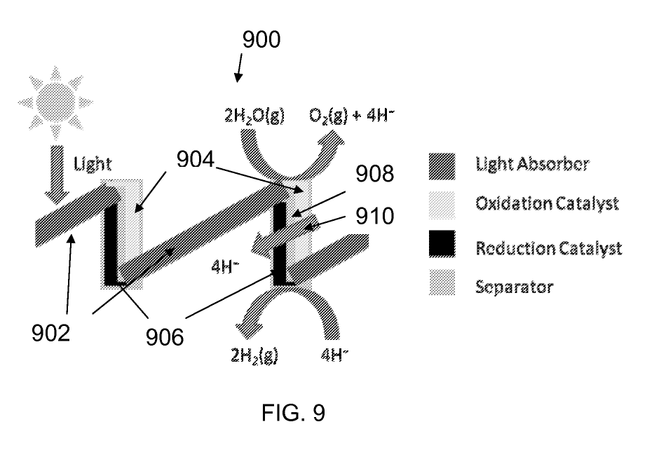

In a third embodiment 900 illustrated in FIG. 9, the separator, the catalysts and light absorber components could be arranged differently than in FIG. 7 or in FIG. 8. In FIG. 9, semiconductor components 902 absorb incident light and generate electrons and holes at a certain potential. The holes go to the anode 904 comprising an oxidation catalyst and oxidize H₂O provided by water vapor. The electrons generated in the light absorber go to the cathode 906 comprising a reduction catalyst and reduce protons (H⁺) to make molecular hydrogen. A separator 908, which can be an ion exchange membrane, separates the oxygen generation region from the hydrogen generation region, but permits a flux (represented by arrow 910) of excess protons (H⁺) to pass from the oxygen generation region to the hydrogen generation region.

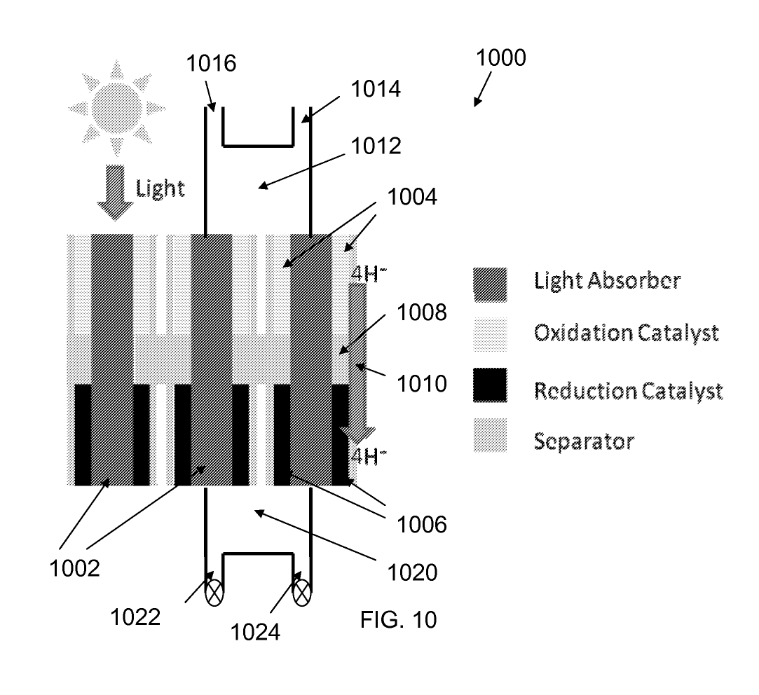

FIG. 10 is a schematic diagram that illustrates a device 1000 that is similar in geometry to the device shown in FIG. 7, but which has several additional or modified structures. In FIG. 10, semiconductor components 1002 absorb incident light and generate electrons and holes at a certain potential. The holes go to the anode 1004 comprising an oxidation catalyst and oxidize H₂O provided by water vapor. The electrons generated in the light absorber go to the cathode 1006 comprising a reduction catalyst and reduce carbon dioxide (CO₂) to make a carbonaceous fuel. A separator 1008, which can be an ion exchange membrane, separates the oxygen generation region from the fuel generation region, but permits a flux (represented by arrow 1010) of excess protons (H⁺) to pass from the oxygen generation region to the carbonaceous fuel generation region, where they are consumed in making the carbonaceous fuel. There is net water consumption in the reactions according to Rxn. 4 given below. However, it should be understood that water may be consumed on the anode side in larger amount than the amount of water that is generated on the cathode side of the apparatus, when the details of the half-reactions that make up the totality of Rxn. 4 are considered.

The device illustrated in FIG. 10 further includes a chamber 1012 having an inlet port 1014 and an outlet port 1016. The chamber is configured to allow water vapor to come into contact with the oxidation catalyst 1004 and with the separator 1008.

In some embodiments, the device illustrated in FIG. 10 has an additional chamber 1020 that can contain a reagent, and that allows the reagent to contact the cathode 1006 and the separator 1008. The chamber 1020 has an inlet port 1022 that includes a valve and an outlet port 1024 that includes a valve. The chamber 1020 can be filled and maintained in a close state by closing the two valves on the inlet port and the outlet port, respectively, so that a reaction can be run in a batch mode. Alternatively, the valves can be maintained in an open condition, so that a reaction can be run in a continuous mode.

In FIG. 7 through FIG. 10, the illumination is shown impinging on the light absorber 702, 802, 902, 1002 from one direction. It is equally acceptable for the light to impinge on the light absorber 702, 802, 902, 1002 from any direction, as long as the illumination will provide sufficient light intensity to operate the device and the light absorber 702, 802, 902, 1002 is sensitive to light coming from that direction. By way of example, some light absorbers can be operated in “front illumination” as well as “rear illumination” modes. The light absorbers 702, 802, 902, 1002 are sensitive to diffuse light as well as collimated or directed light.

One well known reaction that consumes H₂O and CO₂ and generates molecular oxygen and a chemical fuel is the photosynthesis reaction, in which 6 water molecules and 6 carbon dioxide molecules are reacted to produce glucose (sugar) and 6 molecules of oxygen:

6 CO₂+6 H₂O→C₆H₁₂O₆+6 O₂ (Photosynthesis Rxn)

We can write an equation for a generic reaction to produce a hydrocarbon and molecular oxygen from carbon dioxide and water as:

M CO₂+N H₂O→hydrocarbon (C_{M}H_{2N}O_{(2M+N-2P)})+P O₂ (Rxn. 4)

We can describe the reaction as one in which the carbonaceous fuel is a compound having a formula C_{M}H_{2N}O_{(2M+N-2P)}, in which M is an integer giving the number of moles of CO₂ consumed, N is an integer giving the number of moles of H₂O consumed, and P is an integer giving the number of moles of O₂ produced in a chemical reaction that produces one or more moles of C_{M}H_{2N}O_{(2M+N-2P)}. In some instances, the net amount of oxygen that enters the chemical fuel product may be zero, as in the case of generation of methane, CH₄, which consumes one mole of CO₂ and two moles of H₂O , and produces one mole of O₂ for each mole of CH₄ produced. We can also write the generic equation of Rxn. 4 as:

M CO₂+N H₂O→C_{M}H_{Y}O_{Z}+P O₂ (Rxn. 5)

where M, N and P are non-negative numbers and Y=2N, and Z=2M+N−2P, assuming that a single mole of the molecule C_{M}H_{Y}O_{Z} is produced when M moles of CO₂ and N moles of H₂O are reacted.

Table I lists some examples of reactions that can be understood as examples of the general reaction, for various values of M, N, and P. Substances that can be produced as chemical fuels include, but are not limited to, H₂, carbon monoxide (CO), methanol, methane, ethanol, butanol, formic acid and other hydrocarbons and carbohydrates.

TABLE I

| | | | | | Moles |
|---|---|---|---|---|---|
| M | N | P | Carbonaceous fuel | Chemical name | O₂ |
| 1 | 2 | 2 | CH₄ | Methane | 2 |
| 2 | 4 | 3 | 2 molecules CH₃OH | Methanol | 3 |
| | | | produced | | |
| 2 | 2 | 1 | 2 molecules HCOOH | Formic Acid | 1 |
| | | | produced | | |
| 2 | 2 | 2 | CH₃COOH | Acetic acid | 2 |
| 2 | 3 | 3 | C₂H₆O | Ethanol | 3 |
| 3 | 3 | 4 | CH₃CH₂COH | Propanol | 4 |
| 3 | 4 | 4 | HOCH₂CH₂CH₂OH | 1,3-Propanediol | 4 |
| 4 | 3 | 4 | CH₃CH₂COCOOH | 2-oxobutyric acid | 4 |
| 4 | 5 | 6 | CH₃CH₂CH₂COH | Butanol | 6 |
| 6 | 6 | 6 | C₆H₁₂O₆ | Glucose | 6 |

Several reactions in which CO₂ is reduced to generate carbonaceous fuels will now be discussed as examples.

The anode half-reaction for oxidizing water to molecular oxygen is repeated as Rxn. 1:

2 H₂O(g)→O₂(g)+4 H⁺+4 e⁻ (Rxn. 1)

### Methane

The cathode half-reaction that produces methane in a medium having protons is given by Rxn. 6:

CO₂+8H⁺+8e⁻→CH₄+2 H₂O (Rxn. 6)

If we sum 2 times Rxn. 1 with Rxn. 6 in order to balance the protons and electrons (and canceling out equal amounts of water present on each side of the reaction), we obtain as the reaction for the production of methane from CO₂ and H₂O (as given in Table I):

CO₂+2 H₂O(g)→CH₄+2 O₂ (Methane production)

### Methanol

The cathode half-reaction that produces methanol in a medium having protons is given by Rxn. 7:

CO₂+6H⁺+6e⁻→CH₃OH+H₂O (Rxn. 7)

If we sum 3 times Rxn. 1 with 2 times Rxn. 7 in order to balance the protons and electrons, we obtain as the reaction for the production of methanol from CO₂ and H₂O (as given in Table I):

2 CO₂+4 H₂O→2 CH₃OH+ +3O₂ (Methanol production)

### Formic Acid

The cathode half-reaction that produces formic acid in a medium having protons is given by Rxn. 8:

CO₂+2H⁺+2e⁻→HCO₂H (Rxn. 8)

If we sum Rxn. 1 with 2 times Rxn. 8 in order to balance the protons and electrons, we obtain as the reaction for the production of methanol from CO₂ and H₂O (as given in Table I):

2 CO₂+2 H₂O(g)→2 HCO₂H+O₂(g) (Formic acid production)

### Carbon Monoxide

The cathode half-reaction that produces carbon monoxide in a medium having protons is given by Rxn. 9:

CO₂+2H^{|}+2e→CO+H₂O (Rxn. 9)

If we sum Rxn. 1 with 2 times Rxn. 9 in order to balance the protons and electrons, we obtain as the reaction for the production of carbon monoxide (CO) from CO₂ in which no net H₂O is consumed or produced:

2 CO₂+→2 CO+O₂(g) (Carbon monoxide production)

This can be viewed as a special case of the reactions in Table I, in which the entries M=2, N=0 and P=1 are required, and because there are 2 molecules of CO produced, Z=2M+N−2P=4−2=2 must be divided by 2.

In order to carry out such reactions, it is believed that one needs to control variables such as the proportions (or partial pressures) of the reagents, the temperature of the reaction, the voltages applied to the catalysts, and the chemical composition of the catalysts. It is believed that devices constructed and operated according to principles of the invention, using water vapor as a source of water, can be operated to produce molecular oxygen and carbonaceous fuels, analogously to natural photosynthesis. Because photosynthesis occurs at ambient temperatures that are in the vicinity of room temperature (e.g., in the range of 10 to 40° C., and possibly in the range of 0 to 100° C.), it is believed that devices constructed and operated according to principles of the invention can also function at ambient temperatures in similar temperature ranges.

### Catalysts

Oxygen evolution catalysts that can be employed in the apparatus and methods according to the invention include, but are not limited to, ruthenium oxide (RuO₂), iridium oxide (IrO₂), iridium-ruthenium alloy oxide (IrRuOₓ), cobalt oxide (Co₃O₄), manganese oxide (MnO₂), nickel iron oxide (NiFeOₓ), nickel lanthanum oxide (NiLaOₓ), barium strontium cobalt iron oxide (BaSrCoFeOₓ), and platinum (Pt).

Hydrogen evolution catalysts that can be employed in the apparatus and methods according to the invention include, but are not limited to, platinum (Pt), nickel molybdenum (NiMo), and nickel cobalt (NiCo).

Carbon dioxide reduction catalysts that can be employed in the apparatus and methods according to the invention include, but are not limited to, copper (Cu), zinc (Zn), tin (Sn), nickel (Ni), platinum (Pt), palladium (Pd), rhodium (Rh), iridium (Ir) and other metals, as well as various metal porphyrins and phthalocyanines.

Various review and research articles that describe various hydrogen evolution catalysts, oxygen evolution catalysts and various carbon dioxide reduction catalysts include: Michael G. Walter, Emily L. Warren, James R. McKone, Shannon W. Boettcher, Qixi Mi, Elizabeth A. Santori, and Nathan S. Lewis, “Solar Water Splitting Cells,” Chem. Rev. 2010, 110, 6446-6473 (published Nov. 10, 2010); M. A. Scibioh & B. Viswanathan, Proc. Indn. Natl. Acad. Sci., 70 A (3), 2004, 407-462; M. Jitaru, J. Appl. Elec. Chem 27 (1997) 875; J. P. Collin & J. P. Sauvage, Coord. Chem. Rev. 93 (1989) 245; M. Anpo, J. Electroanal Chem 396 (1995) 21; H. Yamashita et al., Catalysis Today 45 (1998) 221; G. Ramirez et al., Inorganica Chimica Acta 362 (2009) 5-10; Bhupendra Kumar, Mark Llorente, Jesse Froehlich, Tram Dang, Aaron Sathrum, and Clifford P. Kubiak, “Photochemical and Photoelectrochemical Reduction of CO₂,” Annu. Rev. Phys. Chem. 2012. 63:24.1-24.29 (Review in Advance first posted online on Jan. 30, 2012).

### Light Absorbers

Various semiconductors are suitable for use in apparatus as shown in FIG. 7, FIG. 8, FIG. 9 and FIG. 10. One choice is p-type silicon, which can function as the absorber on both the anode and cathode sides of the ion exchange membrane. In particular p-type silicon is a candidate for the photocathode material because it is cathodically stable under illumination in acidic aqueous media and has been demonstrated, in conjunction with various metal catalysts, to evolve H₂(g) from H₂O. Other possible choices include semiconductors having wider bandgaps than silicon that are stable in the water vapor medium. Oxide semiconductors are believed to be a possible choice.

By way of example, some of the light absorbers that can be used in the apparatus and methods of the invention include, but are not limited to: tandem structure photoanodes, including tungsten oxide (WO₃), bismuth vanadium oxide (BiVO₄), tantalum oxynitride (TaON), and titanium oxide (TiO₂); tandem structure photocathodes, including silicon (Si), cuprous oxide (Cu₂O), gallium phosphide (GaP), gallium arsenide (GaAs), and indium phosphide (InP); single material photoelectrodes, including strontium titanate (SrTiO₃), strontium niobate (SrNbO₃), and titanium oxide (TiO₂); multijunction photovoltaics, including triple junction amorphous silicon (a-Si), and vertically stacked epitaxially grown III-V semiconductors with tunnel junctions; and series connected photovoltaics, including silicon (Si) cells, gallium arsenide (GaAs) cells, cadmium telluride (CdTe) cells, and Copper Indium Gallium Selenide (CIGS) thin film cells.

### Separators

Separators that can be used in various embodiments include, but are not limited to, Nafion® (polytetrafluoroethylene with sulfonic acid groups), Nafion® functionalized with dimethylpiperazinium cationic groups, glass frits, asbestos fibers, block copolymer formulated layers, and poly(arylene ether sulfone) with quaternary ammonium groups.

### Hydroxide Ion Transport Systems

While we have shown protons as the ion that is transferred across the membrane, in alternative embodiments an analogous process could also be performed at high pH, in which hydroxide ions would transfer instead of protons.

The cathode half reaction is given by

4 H₂O(l)+4 e⁻→2 H₂(g)+4 OH⁻(aq) (Rxn. 10)

and the anode half-reaction is given by

4 OH⁻(aq)→O₂(g)+2 H₂O(l)+4 e⁻. (Rxn. 11)

Summing reactions 10 and 11 (and canceling as much as possible common terms found on each side of the reaction) again gives the same result as in reaction 3 above. The hydroxide ions move from the hydrogen generation side to the oxygen generation side (e.g., in a direction opposite to that of H⁻ as shown in any of FIG. 7, FIG. 8, FIG. 9 and FIG. 10). In such embodiments, a membrane that is capable of transporting hydroxyl ions is substituted for the Nafion® membrane. One possible membrane can be prepared using the anion exchange ionomer poly(arylene ether sulfone) that is functionalized with quaternary ammonium groups (QAPSF) as described in J. F. Zhou, M. Unlu, J. A. Vega and P. A. Kohl, J. Power Sources, 2009, 190, 285-292.

In the case of water vapor electrolysis to produce molecular oxygen and molecular hydrogen as the chemical fuel, the separator/ion exchange membrane provides a transport path from the water vapor in contact with one type of catalytic site to the water vapor in contact with the other type of catalytic site, so that the generated protons, H⁺, or hydroxide ions, OH⁻, can move through the membrane to the other side. In the case of reactions involving H₂O and CO₂ to produce molecular oxygen and a carbonaceous chemical as the chemical fuel, it is believed that the separator/ion exchange membrane also provides a transport path from the water vapor in contact with one type of catalytic site to the water vapor in contact with the other type of catalytic site (a CO₂ reduction catalyst), so that the generated protons, H⁺, or hydroxide ions, OH⁻, can move through the membrane to the other side.

### Theoretical Discussion

Although the theoretical description given herein is thought to be correct, the operation of the devices described and claimed herein does not depend upon the accuracy or validity of the theoretical description. That is, later theoretical developments that may explain the observed results on a basis different from the theory presented herein will not detract from the inventions described herein.

Any patent, patent application, or publication identified in the specification is hereby incorporated by reference herein in its entirety. Any material, or portion thereof, that is said to be incorporated by reference herein, but which conflicts with existing definitions, statements, or other disclosure material explicitly set forth herein is only incorporated to the extent that no conflict arises between that incorporated material and the present disclosure material. In the event of a conflict, the conflict is to be resolved in favor of the present disclosure as the preferred disclosure.

While the present invention has been particularly shown and described with reference to the preferred mode as illustrated in the drawing, it will be understood by one skilled in the art that various changes in detail may be affected therein without departing from the spirit and scope of the invention as defined by the claims.

What is claimed is:

1. An illumination-driven apparatus, comprising:
a separator having a first side and a second side opposite said first side, said separator configured to be permeable to an ionic reaction moiety and configured to be substantially impermeable to molecular moieties so as to separate a first molecular moiety present on said first side from a second molecular moiety present on said second side;
an oxidation catalyst present on said first side of said separator, said oxidation catalyst configured to oxidize H₂O to produce molecular oxygen;
a reduction catalyst present on said second side of said separator, said reduction catalyst configured to reduce a substance to produce a chemical fuel;
a source of water vapor, said water vapor permitted to contact said first side of said separator and said oxidation catalyst; and
a light absorber configured to absorb illumination, configured to provide electrons at a voltage sufficient to drive a desired chemical half-reaction at said reduction catalyst, and configured to accept electrons so as to drive another desired chemical half-reaction at said oxidation catalyst, said light absorber and said separator in mechanical contact so as to form a monolithic structure.

2. The illumination-driven apparatus of claim 1, further comprising a first inlet port configured to permit the introduction of water vapor into said apparatus and a first outlet port configured to allow molecular oxygen to exit said apparatus.

3. The illumination-driven apparatus of claim 1, wherein said chemical fuel is H₂.

4. The illumination-driven apparatus of claim 1, wherein said chemical fuel is a carbonaceous fuel.

5. The illumination-driven apparatus of claim 4, wherein said carbonaceous fuel is a compound having a formula C_{M}H_{2N}O_{(2M+N-2P)}, in which M is an integer giving the number of moles of CO₂ consumed, N is an integer giving the number of moles of H₂O consumed, and P is an integer giving the number of moles of O₂ produced in a chemical reaction that produces one or more moles of C_{M}H_{2N}O_{(2M+N-2P)}.

6. The illumination-driven apparatus of claim 1, wherein said ionic reaction moiety is H⁺.

7. The illumination-driven apparatus of claim 1, further comprising:
a chamber configured to contain a reagent, said chamber configured to permit said reagent to contact said second side of said separator and said reduction catalyst.

8. The illumination-driven apparatus of claim 7, further comprising:
a second inlet port configured to permit the introduction of said reagent into said chamber and a second outlet port configured to permit the removal of said chemical fuel from said chamber.

9. The illumination-driven apparatus of claim 1, wherein said light absorber configured to absorb illumination is configured to absorb illumination having an intensity of approximately 1 kilowatt per square meter or less.

10. The illumination-driven apparatus of claim 9, wherein said illumination having an intensity of approximately 1 kilowatt per square meter or less is terrestrial solar illumination.

11. The illumination-driven apparatus of claim 1, wherein said ionic reaction moiety is OH⁻.

12. A method of generating a chemical fuel and molecular oxygen from a reaction medium containing water vapor, comprising the steps of:
providing an illumination-driven apparatus, comprising:
a separator having a first side and a second side opposite said first side, said separator configured to be permeable to an ionic reaction moiety and configured to be substantially impermeable to molecular moieties so as to separate a first molecular moiety present on said first side from a second molecular moiety present on said second side;
an oxidation catalyst present on said first side of said separator, said oxidation catalyst configured to oxidize H₂O to produce molecular oxygen;
a reduction catalyst present on said second side of said separator, said reduction catalyst configured to reduce a substance to produce a chemical fuel;
a source of water vapor, said water vapor permitted to contact said first side of said separator and said oxidation catalyst; and
a light absorber configured to absorb illumination, configured to provide electrons at a voltage sufficient to drive a desired chemical half-reaction at said reduction catalyst, and configured to accept electrons so as to drive another desired chemical half-reaction at said oxidation catalyst, said light absorber and said separator in mechanical contact so as to form a monolithic structure;
providing water vapor that contacts said first side of said separator and said oxidation catalyst;
illuminating said light absorber;
oxidizing H₂O to molecular oxygen at said oxidation catalyst;
permitting H⁺ ions to permeate said separator; and
performing a reduction at said reduction catalyst to produce a chemical fuel comprising hydrogen.

13. The method of generating a chemical fuel and molecular oxygen from a reaction medium containing water vapor of claim 12, wherein said illumination-driven apparatus further comprises a first inlet port configured to permit the introduction of water vapor into said apparatus and a first outlet port configured to allow molecular oxygen to exit said apparatus.

14. The method of generating a chemical fuel and molecular oxygen from a reaction medium containing water vapor of claim 12, wherein said method is operated in a continuous process.

15. The method of generating a chemical fuel and molecular oxygen from a reaction medium containing water vapor of claim 12, wherein said reduction catalyst is a catalyst that reduces CO₂ to produce a carbonaceous fuel.

16. The method of generating a chemical fuel and molecular oxygen from a reaction medium containing water vapor of claim 15, wherein
said illumination-driven apparatus further comprises a chamber configured to contain a reagent, said chamber configured to permit said reagent to contact said second side of said separator and said reduction catalyst; and
said method further comprises the steps of:
providing a reagent containing CO₂ within said chamber; and
performing said reduction step on a mixture of said reagent and said H+ ions to produce a chemical fuel comprising hydrogen and carbon.

17. The method of generating a chemical fuel and molecular oxygen from a reaction medium containing water vapor of claim 16, wherein said method is operated in a batch process.

18. The method of generating a chemical fuel and molecular oxygen from a reaction medium containing water vapor of claim 16, wherein said illumination-driven apparatus further comprises a second inlet port configured to permit the introduction of said reagent into said chamber and a second outlet port configured to permit the removal of said chemical fuel from said chamber, said illumination-driven apparatus thereby enabled to support continuous operation of said step of oxidizing H₂O to molecular oxygen at said oxidation catalyst and continuous operation of said step of performing a reduction at said reduction catalyst to produce a chemical fuel comprising hydrogen.

19. The method of generating a chemical fuel and molecular oxygen from a reaction medium containing water vapor of claim 18, wherein said method is operated in a continuous process.

20. The method of generating a chemical fuel and molecular oxygen from a reaction medium containing water vapor of claim 12, wherein said illuminating step uses illumination having an intensity of approximately 1 kilowatt per square meter or less.

21. The method of generating a chemical fuel and molecular oxygen from a reaction medium containing water vapor of claim 12, wherein said illuminating step uses terrestrial solar illumination.
